(19) United States
(12) Patent Application Publication
(10) Pub. No.: US 2026/0349460 A1
(43) Pub. Date: Nov. 5, 2026

(54) SELECTABLE REFERENCE VOLTAGE OUTPUT

(71) Applicant: Microchip Touch Solutions Limited, Wokingham (GB)

(72) Inventors: Naveen Raj, Chandler, AZ (US); Pat Richards, Peoria, AZ (US); John Austin, Chandler, AZ (US); Daniel Meacham, Del Mar, CA (US); Ashfaq Alam Juna, Winnersh (GB)

(73) Assignee: Microchip Touch Solutions Limited, Wokingham (GB)

(21) Appl. No.: 19/315,934

(22) Filed: Sep. 2, 2025

Related U.S. Application Data
(60) Provisional application No. 63/797,205, filed on Apr. 30, 2025.

(51) Int. Cl. G05F 1/46; G11C 5/14

(52) U.S. Cl. CPC G05F 1/468; G05F 1/465; G11C 5/148

(57) ABSTRACT

A system and method for providing a selectable reference voltage output are disclosed. The reference voltage integrated circuit may include a volatile memory for storing an output voltage selection. The output voltage selection may be selectable between a first value corresponding to a first reference voltage and a second value corresponding to a second reference voltage. The reference voltage integrated circuit may also include a pin for selecting between the first reference voltage and the second reference voltage. The reference voltage integrated circuit may further include a reference voltage output pin for outputting the selected reference voltage.

### PRIORITY

This application claims priority to U.S. Provisional Patent Application No. 63/797,205 filed Apr. 30, 2025, the contents of which are hereby incorporated in their entirety.

### TECHNICAL FIELD

The present disclosure relates to providing a reference voltage, and in particular, to a system and method for providing a selectable reference voltage output.

### BACKGROUND

In electronic circuits, a reference voltage serves as a stable and known voltage potential used as a benchmark for comparison or measurement. The primary function of a reference voltage is to provide a fixed point against which other, potentially varying, voltages within the circuit can be accurately measured or controlled. For example, in an analog-to-digital converter (ADC), the reference voltage defines the full-scale range. The ADC converts an analog input voltage into a digital value representing the input's proportion relative to this reference. Similarly, digital-to-analog converters (DACs) use a reference voltage to scale their output, generating an analog voltage that is a specific fraction of the reference based on the digital input code. Comparators also rely on reference voltages, switching their output state when an input voltage crosses the threshold set by the reference.

The reference voltage may be provided by a dedicated voltage reference integrated circuit designed to output a precise, stable voltage regardless of changes in input voltage, output load current, and ambient temperature. A voltage reference integrated circuit may provide a single voltage reference.

### SUMMARY OF THE INVENTION

Aspects provide systems and methods for providing a selectable reference voltage output. Examples of the present disclosure may include a reference voltage integrated circuit. The reference voltage integrated circuit may include a volatile memory for storing an output voltage selection. The output voltage selection may be selectable between a first value corresponding to a first reference voltage and a second value corresponding to a second reference voltage. The reference voltage integrated circuit may also include a pin for selecting between the first reference voltage and the second reference voltage. The reference voltage integrated circuit may further include a reference voltage output pin for outputting the selected reference voltage.

In combination with any of the above examples, the reference voltage integrated circuit may include a non-volatile memory for storing a first trim register and a second trim register. The first trim register may correspond to the first value corresponding to the first reference voltage and the second trim register may correspond to the second value corresponding to the second reference voltage.

In combination with any of the above examples, the pin may be configured to be communicatively coupled to a control circuit. The pin may be configured to receive, from the control circuit, a command to select between the first value of the output voltage selection and the second value of the output voltage selection.

In combination with any of the above examples, the pin may be configured to receive, from the control circuit, a command to place the reference voltage integrated circuit in a shutdown state.

In combination with any of the above examples, the pin may be configured to be communicatively coupled to the control circuit via an inter-integrated circuit (I2C) interface.

In combination with any of the above examples, the pin is configured to be at a first state and a second state. When the pin is at the first state, the first reference voltage may be selected. When the pin is at the second state, the second reference voltage is selected.

In combination with any of the above examples, the reference voltage integrated circuit may include a second pin configured to be at a third state and a fourth state. The output voltage selection may be configured to be selectable between the first value, the second value, and a third value corresponding to a third reference voltage. When the pin is at the first state and the second pin is at the fourth state, the first reference voltage may be selected. When the pin is at the second state and the second pin is at the fourth state, the second reference voltage may be selected. When the pin is at the second state and the second pin is at the third state, the third reference voltage may be selected. When the pin is at the first state and the second pin is at the third state, the reference voltage integrated circuit may be placed in a shutdown state.

Alone or in combination with any of the above examples, examples of the present disclosure may include a method. The method may include storing, in a volatile memory, an output voltage selection, the output voltage selection selectable between a first value corresponding to a first reference voltage and a second value corresponding to a second reference voltage. The method may also include selecting between the first reference voltage and the second reference voltage. The method may further include outputting, using a reference voltage output pin, the selected reference voltage.

In combination with any of the above examples, the method may include storing, in a non-volatile memory, a first trim register and a second trim register. The first trim register may correspond to the first value corresponding to the first reference voltage and the second trim register may correspond to the second value corresponding to the second reference voltage.

In combination with any of the above examples, the method may include communicatively coupling a control circuit. The method may also include receiving, from the control circuit, a command to select between the first value of the output voltage selection and the second value of the output voltage selection.

In combination with any of the above examples, the method may include receiving, from the control circuit, a command to place a reference voltage integrated circuit in a shutdown state.

In combination with any of the above examples, the control circuit may be communicatively coupled using an inter-integrated circuit (I2C) interface.

In combination with any of the above examples, the method may include setting a pin to a first state or a second state. The method may also include selecting the first reference voltage when the pin is at the first state. The method may further include selecting the second reference voltage when the pin is at the second state.

In combination with any of the above examples, the method may include setting a first pin to a first state or a second state. The method may also include setting a second pin to a third state and a fourth state, wherein the output voltage selection is configured to be selectable between the first value, the second value, and a third value corresponding to a third reference voltage. The method may additionally include selecting the first reference voltage when the first pin is at the first state and the second pin is at the fourth state. The method may include selecting the second reference voltage when the first pin is at the second state and the second pin is at the fourth state. The method may also include selecting the third reference voltage when the first pin is at the second state and the second pin is at the third state. The method may further include placing a reference voltage integrated circuit in a shutdown state when the first pin is at the first state and the second pin is at the third state.

Alone or in combination with any of the above examples, examples of the present disclosure may include a reference voltage integrated circuit. The reference voltage integrated circuit may include a volatile memory for storing an output voltage selection. The output voltage selection may be selectable between a first value corresponding to a first reference voltage and a second value corresponding to a second reference voltage. The reference voltage integrated circuit may also include a non-volatile memory for storing a first trim register and a second trim register. The first trim register may correspond to the first value corresponding to the first reference voltage and the second trim register may correspond to the second value corresponding to the second reference voltage. The reference voltage integrated circuit may additionally include a pin for selecting between the first reference voltage and the second reference voltage. The reference voltage integrated circuit may further include a reference voltage output pin for outputting the selected reference voltage.

In combination with any of the above examples, the pin may be configured to be communicatively coupled to a control circuit. The pin may be configured to receive, from the control circuit, a command to select between the first value of the output voltage selection and the second value of the output voltage selection.

In combination with any of the above examples, the pin may be configured to receive, from the control circuit, a command to place the reference voltage integrated circuit in a shutdown state.

In combination with any of the above examples, the first trim register and the second trim register may be configured to be set during a production trimming process.

In combination with any of the above examples, the pin may be configured to be at a first state and a second state. When the pin is at the first state, the first reference voltage may be selected. When the pin is at the second state, the second reference voltage may be selected.

In combination with any of the above examples, the reference voltage integrated circuit may include a second pin configured to be at a third state and a fourth state. The output voltage selection may be configured to be selectable between the first value, the second value, and a third value corresponding to a third reference voltage. When the pin is at the first state and the second pin is at the fourth state, the first reference voltage may be selected. When the pin is at the second state and the second pin is at the fourth state, the second reference voltage may be selected. When the pin is at the second state and the second pin is at the third state, the third reference voltage may be selected. When the pin is at the first state and the second pin is at the third state, the reference voltage integrated circuit may be placed in a shutdown state.

### BRIEF DESCRIPTION OF THE DRAWINGS

The figures illustrate examples of systems and methods for providing a selectable reference voltage output.

FIG. 1 illustrates a pinout of a selectable reference voltage integrated circuit, according to examples of the present disclosure;

FIG. 2 illustrates a system including a selectable reference voltage integrated circuit, according to examples of the present disclosure;

FIGS. 3A and 3B illustrate a system including a selectable reference voltage integrated circuit, according to examples of the present disclosure;

FIG. 4 illustrates a method performed for selecting a reference voltage output for a selectable reference voltage integrated circuit, according to examples of the present disclosure; and

FIGS. 5A and 5B illustrate a more detailed method performed for selecting a reference voltage output for a selectable reference voltage integrated circuit, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, systems and methods for providing a selectable reference voltage output are disclosed. A selectable reference voltage integrated circuit may provide access to one or more pins of the integrated circuit such that a user may select the reference voltage output by the integrated circuit. The selectable reference voltage integrated circuit may be useful for applications where multiple reference voltages may be used at different times. For example, the selectable reference voltage integrated circuit may be used in battery powered applications where the power supply voltage (V_{DD}) may be reduced and the reference voltage may also be reduced based on the V_{DD}. As another example, the selectable reference voltage integrated circuit may be used in applications where the hardware may be modified based on changes in the environment, resulting in a different reference voltage.

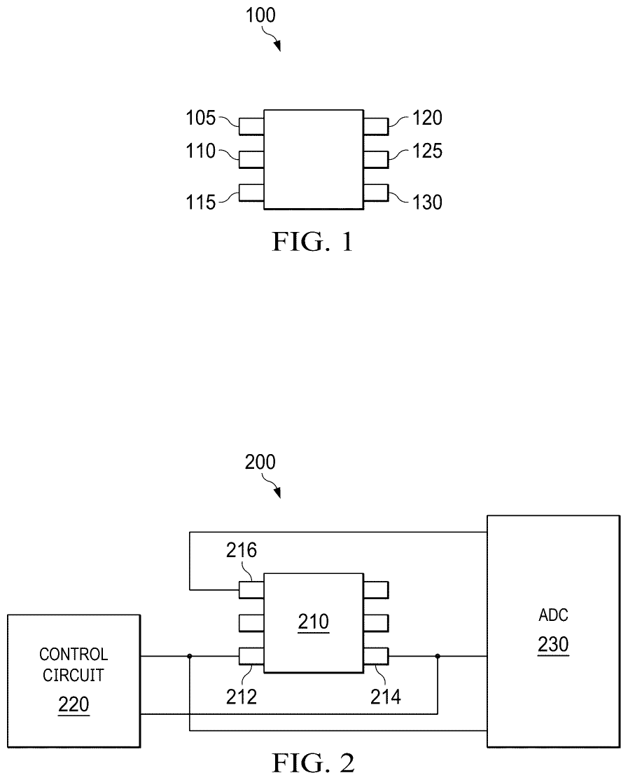

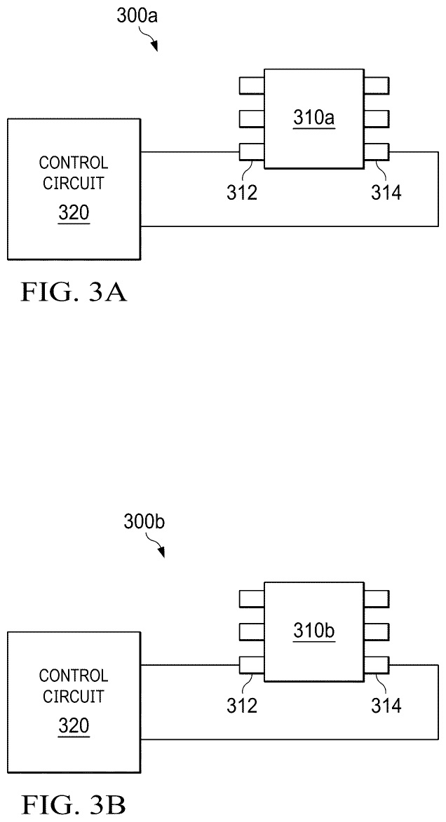

FIG. 1 illustrates a pinout of a selectable reference voltage integrated circuit, according to examples of the present disclosure. Integrated circuit 100 may include a plurality of pins, including but not limited to, reference voltage output pin 105, ground pin 110, voltage selection pin 115, power supply input pin 120, reference voltage feedback pin 125, and shutdown pin 130. One or more pins, such as voltage selection pin 115 or shutdown pin 130, may be exposed to the user to allow the user to select the reference voltage output at reference voltage output pin 105. For example, voltage selection pin 115, shutdown pin 130, or both may be communicatively coupled to an inter-integrated circuit (I2C) connection or a serial peripheral interface (SPI) connection and coupled to a control circuit, as described in further detail with reference to FIG. 2. The user may provide inputs to voltage selection pin 115, shutdown pin 130, or both to select from reference voltage options for integrated circuit 100. For example, integrated circuit 100 may be configured to output a reference voltage of 2.048 volts (V), 2.5 V, or 3.3 V. The user may provide inputs to the voltage selection pin 115, shutdown pin 130, or both to select from among those reference voltage options.

FIG. 2 illustrates a system including a selectable reference voltage integrated circuit, according to examples of the present disclosure. System 200 may include selectable reference voltage integrated circuit 210, control circuit 220, and analog-to-digital converter (ADC) 230.

Selectable reference voltage integrated circuit 210 may be similar to integrated circuit 100 shown in FIG. 1. Selectable reference voltage integrated circuit 210 may include input pins 212 and 214 and reference voltage output pin 216. Selectable reference voltage integrated circuit 210 may include additional pins not expressly labeled, such as a ground pin, a power supply input pin, and a power supply input pin, as described with reference to integrated circuit 100 shown in FIG. 1.

Input pins 212 and 214 may be exposed to a user and may be communicatively coupled to control circuit 220. Reference voltage output pin 216 may output the reference voltage to ADC 230. The reference voltage output on reference voltage output pin 216 may be selectable by a user accessing a register in integrated circuit 210 via control circuit 220 and input pins 212 and 214, as described in more detail below.

Control circuit 220 may be implemented by instructions for execution by a processor, analog circuitry, digital circuitry, control logic, digital logic circuits programmed through hardware description language, application specific integrated circuits (ASIC), field programmable gate arrays (FPGA), programmable logic devices (PLD), or any suitable combination thereof, whether in a unitary device or spread over several devices. Control circuit 220 may be implemented by instructions for execution by a processor through, for example, a function, application programming interface (API) call, script, program, compiled code, interpreted code, binary, executable, executable file, firmware, object file, container, assembly code, or object. For example, control circuit 220 may be implemented by instructions stored in a non-transitory medium such as a memory that, when loaded and executed by a processor such as a central processing unit (CPU) (or any other suitable process), cause the functionality of control circuit 220 described herein.

ADC 230 may be communicatively coupled to reference voltage output pin 216 and may convert an analog input voltage into a digital value representing the proportion of the analog input voltage relative to the reference voltage output at reference voltage output pin 216. While the example shown in FIG. 2 uses ADC 230 as the device coupled to the output of reference voltage output pin 216, in other examples other devices may be coupled to the output of reference voltage output pin 216, such as a digital-to-analog converter (DAC), comparator, amplifier, or any other device that uses a stable voltage for measurement or operation.

Integrated circuit 210 may include one or more registers used to trim the output voltage of integrated circuit 210. For example, during a production trimming process, a manufacturer may test a given integrated circuit 210 and adjust, or trim, the internal components of integrated circuit 210 to fine-tune the output voltage of integrated circuit 210. A digital code representing the adjustment may be stored in a register of integrated circuit 210. The register may be stored in non-volatile memory on integrated circuit 210, such as, but not limited to, one time programmable (OTP) memory or electronically erasable programmable read-only memory (EEPROM).

To allow a user to select the reference voltage of integrated circuit 210, integrated circuit 210 may have an output voltage selection register. The output voltage selection register may be stored in volatile memory of integrated circuit 210 and exposed to the user via an I2C or SPI connection with control circuit 220. A user may use software on control circuit 220 to edit the value in the output voltage selection register to select the reference voltage output at reference voltage output pin 216. For example, the user may access the output voltage selection register using control circuit 220. The user may modify the value of the output voltage selection register to select a value corresponding to the selected reference voltage. Integrated circuit 210 may be configured to provide a plurality of options for the reference voltage.

As an example, integrated circuit 210 may be configured to provide a reference voltage of either 1.8 volts (V) or 3.3 V, based on the value of output voltage selection register (e.g., the value of the output voltage selection register may be set to 010 for a 1.8 V reference voltage or 110 for a 3.3 V reference voltage). Using control circuit 220, the user may modify the value of the output voltage selection register to set the value to either 010 or 110, depending on the reference voltage the user wishes to select. In another example, integrated circuit 210 may be configured to provide a reference voltage of 1.8 V, 2.5 V, or 3.3 V, based on the value of output voltage selection register (e.g., the value of the output voltage selection register may be set to 010 for a reference voltage of 1.8 V, 100 for a reference voltage of 2.5 V, or 110 for a reference voltage of 3.3 V). Using control circuit 220, the user may modify the value of the output voltage selection register to set the value to either 010, 100, or 110, depending on the reference voltage the user wishes to select. Integrated circuit 210 may be configured to provide any number of combinations of reference voltages, based on the options provided by the manufacturer.

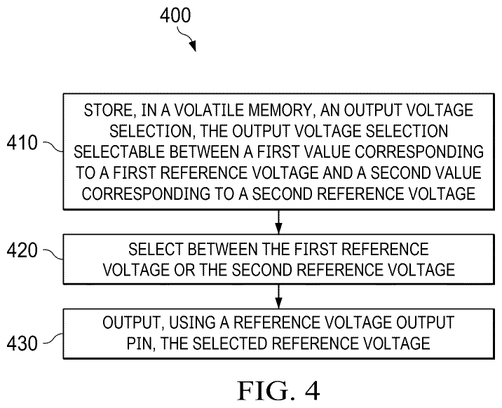

In other examples, the user may select the reference voltage using an input/output (I/O) selection method. The use of an I/O selection method may remove the use of an I2C or SPI interface to select the reference voltage of the integrated circuit. FIGS. 3A and 3B illustrate a system including a selectable reference voltage integrated circuit, according to examples of the present disclosure. System 300a may include selectable reference voltage integrated circuit 310a and control circuit 320. System 300b may include selectable reference voltage integrated circuit 310b and control circuit 320. Selectable reference voltage integrated circuits 310a and 310b may be similar to integrated circuit 100 and integrated circuit 210 shown in FIGS. 1 and 2, respectively. Control circuit 320 may be similar to control circuit 220 shown in FIG. 2. Pins 312 and 314 may be reference voltage selection pins.

Instead of the user editing an output voltage selection register, the user may use control circuit 320 to set a value of output pins 312 and 314 to select the reference voltage output by selectable reference voltage integrated circuit 310a. FIG. 3A illustrates an example where integrated circuit 310a may be configured to provide two different reference voltages. Where integrated circuit 310a is configured to provide two reference voltages, one pin 312 may be used to indicate the user's selection. For example, when pin 312 is set to low, a first reference voltage is selected and when voltage pin 312 is set to high, a second reference voltage is selected, as shown in Table 1. While the example describes pin values as high or low, the pin values may be any suitable different values, such as a first value and a second value.

TABLE 1
Selection Between Two Reference Voltages

| Pin 312 Value | Reference Voltage Output |
|---|---|
| LOW | Voltage 1 |
| HIGH | Voltage 2 |

FIG. 3B illustrates an example where integrated circuit 310b may have three possible reference voltages. Where integrated circuit 310b is configured to provide three reference voltages, two pins 312 and 314 may be used to indicate the user's selection. For example, when pin 312 is low and pin 314 is low, a first reference voltage is selected. When pin 312 is low and pin 314 is high, a second reference voltage is selected. When pin 312 is high and pin 314 is low, a third reference voltage is selected. When pin 312 is high and pin 314 is high, a shutdown mode is selected, as shown in Table 2. While the example describes pin values as high or low, the pin values may be any suitable different values, such as a first value and a second value.

TABLE 2
Selection Between Three Reference Voltages and Shutdown Mode

| Pin 312 Value | Pin 314 Value | Reference Voltage Output |
|---|---|---|
| LOW | LOW | Voltage 1 |
| LOW | HIGH | Voltage 2 |
| HIGH | LOW | Voltage 3 |
| HIGH | HIGH | Shutdown mode |

The I/O reference voltage selection may be implemented for any number of reference voltage options. The number of reference voltage options may be based on the number of output pins available on the integrated circuit for providing values to select a reference voltage.

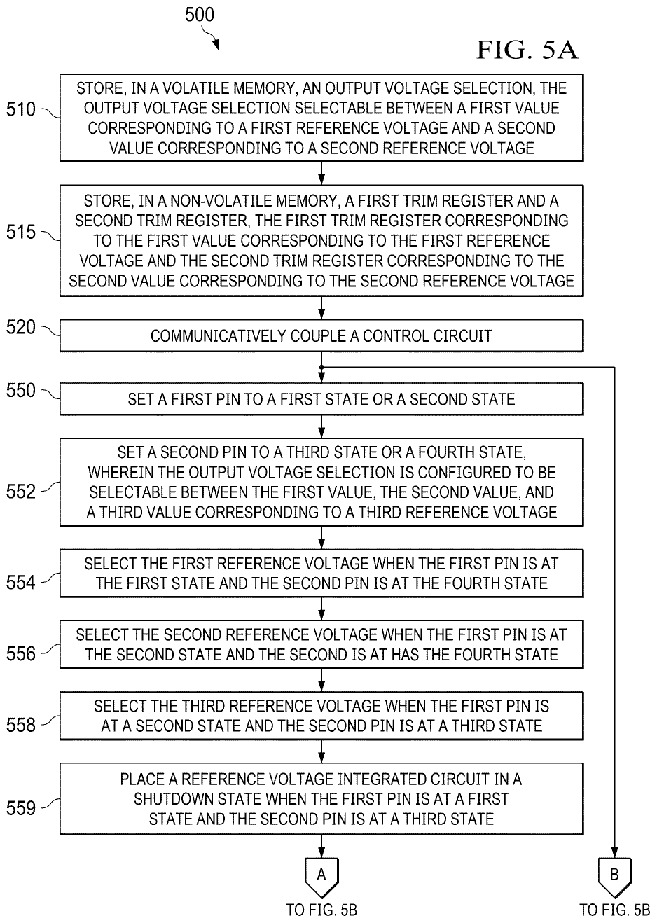

FIG. 4 illustrates a method performed for selecting a reference voltage output for a selectable reference voltage integrated circuit, according to examples of the present disclosure. Method 400 may be implemented using any suitable reference voltage integrated circuit, in combination with a control circuit, or any other system operable to implement method 400. For example, method 400 may be implemented using selectable voltage integrated circuit 100, 210, 310a, or 310b shown in FIGS. 1, 2, 3A, and 3B, respectively, in combination with control circuit 220 or 320 shown in FIGS. 2, 3A, and 3B, respectively. Although examples have been described above, other variations and examples may be made from this disclosure without departing from the spirit and scope of these disclosed examples.

Method 400 may begin at block 410 where an output voltage selection may be stored in a volatile memory of a selectable reference voltage integrated circuit. The output voltage selection may be selectable between a first value corresponding to a first reference voltage and a second value corresponding to a second reference voltage. For example, the selectable reference voltage integrated circuit may be configured to output either the first reference voltage or the second reference voltage.

At block 420, a selection may be made between the first reference voltage and the second reference voltage. In some examples, the selection may be made by editing a value in an output voltage selection register. As described in more detail with respect to FIG. 2, a user may use software on a control circuit to edit the value in the output voltage selection register to select the reference voltage output at a reference voltage output pin of the selectable reference voltage integrated circuit. For example, the user may modify the value of the output voltage selection register to be a first value corresponding to the first reference voltage or to be a second value corresponding to the second reference voltage. In other examples, the selection may be made by using an I/O selection method, as described in more detail with respect to FIGS. 3A and 3B. The user may use a control circuit to set one or more reference voltage selection pins to high or low values corresponding to the first reference voltage and the second reference voltage.

At block 430, the selected reference voltage may be output from the selectable reference voltage integrated circuit using a reference voltage output pin. The selectable reference voltage integrated circuit may output, on a reference voltage pin, the first reference voltage or the second reference voltage based on the selection made at block 420.

Although FIG. 4 discloses a particular number of operations related to method 400, method 400 may be executed with greater or fewer operations than those depicted in FIG. 4 In addition, although FIG. 4 discloses a certain order of operations to be taken with respect to method 400, the operations comprising method 400 may be completed in any suitable order.

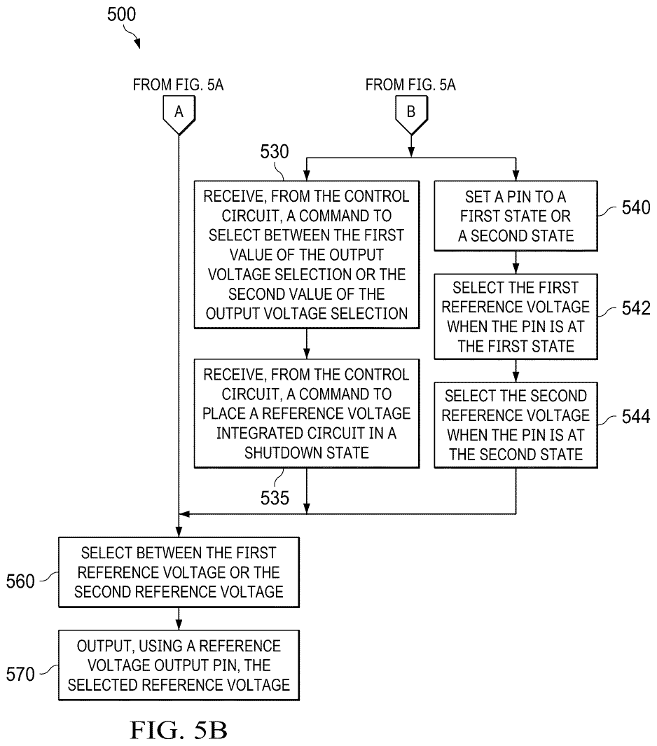

FIGS. 5A and 5B illustrate a more detailed method performed for selecting a reference voltage output for a selectable reference voltage integrated circuit, according to examples of the present disclosure. Method 500 may be implemented using any suitable reference voltage integrated circuit, in combination with a control circuit, or any other system operable to implement method 500. For example, method 500 may be implemented using selectable voltage integrated circuit 100, 210, 310a, or 310b shown in FIGS. 1, 2, 3A, and 3B, respectively, in combination with control circuit 220 or 320 shown in FIGS. 2, 3A, and 3B, respectively. Although examples have been described above, other variations and examples may be made from this disclosure without departing from the spirit and scope of these disclosed examples.

Method 500 may begin at block 510 where an output voltage selection may be stored in a volatile memory of a selectable reference voltage integrated circuit. The output voltage selection may be selectable between a first value corresponding to a first reference voltage and a second value corresponding to a second reference voltage. For example, the selectable reference voltage integrated circuit may be configured to output either the first reference voltage or the second reference voltage.

At block 515, a first trim register and a second trim register, the first trim register corresponding to the first value corresponding to the first reference voltage and the second trim register corresponding to the second value corresponding to the second reference voltage may be stored in a non-volatile memory, such as OTP memory or EEPROM. During a production trimming process, the manufacturer of the selectable reference voltage integrated circuit may test the integrated circuit at the possible reference voltages and store a trim associated with a given reference voltage in a register on the integrated circuit. The integrated circuit may be trimmed at the first reference voltage. A trim adjustment for the first reference voltage may be stored in the first trim register. The integrated circuit may be also trimmed at the second reference voltage. A trim adjustment for the second reference voltage may be stored in the second trim register. The values of these registers may be locked after being saved in the non-volatile memory.

At block 520, the selectable reference voltage integrated circuit may be communicatively coupled to a control circuit. The selectable reference voltage integrated circuit may be communicatively coupled to the control circuit may be coupled using an I2C interface or an SPI interface. After the selectable reference voltage integrated circuit is communicatively coupled to the control circuit, a user may provide an input to select between the first reference voltage and the second reference voltage using any suitable method. For example, the user may provide the selection using the process described with respect to blocks 530 and 535, the process described with respect to blocks 540, 542, and 544, or the process described with respect to blocks 550, 552, 554, 556, 558, and 559.

At block 530, a command to select between the first value of the output voltage selection or the second value of the output voltage selection may be received from the control circuit. Specifically, the selection may be made by editing a value in an output voltage selection register. As described in more detail with respect to FIG. 2, a user may use software on a control circuit to edit the value in the output voltage selection register to select the reference voltage output at a reference voltage output pin of the selectable reference voltage integrated circuit. For example, the user may modify the value of the output voltage selection register to be a first value corresponding to the first reference voltage or to be a second value corresponding to the second reference voltage. At block 535, a command to place a selectable reference voltage integrated circuit in a shutdown state may be received from the control circuit. For example, placing the selectable reference voltage integrated circuit in a shutdown state may be implemented using digital logic inside the integrated circuit. A user may provide a digital code which may interpreted as the command and place the integrated circuit into shut down. As a specific example, a user may write 0x55 (or any other suitable hex value) to shut down mode and 0xAA (or any other suitable hex value) to come out of shut down mode. The digital logic inside the integrated circuit may recognize the hex value (e.g., 0x55 or 0xAA) and take appropriate action.

At block 540, a pin may be set to a first state or a second state. The pin may be a reference voltage selection pin. For example, the selection may be made by using an I/O selection method, as described in more detail with respect to FIG. 3A. At block 542, the selectable reference voltage integrated circuit may select the first reference voltage with the pin is at the first state and at block 544, the selectable reference voltage integrated circuit may select the second reference voltage with the pin is at the second state.

At block 550, a first pin may be set to a first state or a second state. For example, the selection may be made by using an I/O selection method, as described in more detail with respect to FIG. 3B. At block 552, a second pin may be set to a third state or a fourth state. The selectable reference voltage integrated circuit may be configured to be selectable between the first value corresponding to the first reference voltage, the second value corresponding to the second reference voltage, and a third value corresponding to a third reference voltage. At block 554, the selectable reference voltage integrated circuit may select the first reference voltage when the first pin is at the first state and the second pin is at the fourth state. At block 556, the selectable reference voltage integrated circuit may select the second reference voltage when the first pin is at the second state and the second pin is at the fourth state. At block 558, the selectable reference voltage integrated circuit may select the third reference voltage when the first pin is at the second state and the second pin is at the third state. At block 559, the selectable reference voltage integrated circuit may be placed in a shutdown state when the first pin is at the first state and the second pin is at the third state.

At block 560, a selection may be made between the first reference voltage and the second reference voltage based on the selections made at blocks 530 and 535, blocks 540, 542, and 544, or blocks 550, 552, 554, 556, 558, and 559.

At block 570, the selected reference voltage may be output from the selectable reference voltage integrated circuit using a reference voltage output pin. The selectable reference voltage integrated circuit may output, on a reference voltage pin, the first reference voltage or the second reference voltage based on the selection made at block 560.

Although FIGS. 5A and 5B disclose a particular number of operations related to method 500, method 500 may be executed with greater or fewer operations than those depicted in FIGS. 5A and 5B. In addition, although FIGS. 5A and 5B disclose a certain order of operations to be taken with respect to method 500, the operations comprising method 500 may be completed in any suitable order.

Although examples have been described above, other variations and examples may be made from this disclosure without departing from the spirit and scope of these disclosed examples.

1. A reference voltage integrated circuit, comprising:
a volatile memory for storing an output voltage selection, the output voltage selection selectable between a first value corresponding to a first reference voltage and a second value corresponding to a second reference voltage;
a pin for selecting between the first reference voltage and the second reference voltage; and
a reference voltage output pin for outputting the selected reference voltage.

2. The reference voltage integrated circuit of claim 1, comprising a non-volatile memory for storing a first trim register and a second trim register, the first trim register corresponding to the first value corresponding to the first reference voltage and the second trim register corresponding to the second value corresponding to the second reference voltage.

3. The reference voltage integrated circuit of claim 1, wherein:
the pin is configured to be communicatively coupled to a control circuit; and
the pin is configured to receive, from the control circuit, a command to select between the first value of the output voltage selection and the second value of the output voltage selection.

4. The reference voltage integrated circuit of claim 3, wherein the pin is configured to receive, from the control circuit, a command to place the reference voltage integrated circuit in a shutdown state.

5. The reference voltage integrated circuit of claim 3, wherein the pin is configured to be communicatively coupled to the control circuit via an inter-integrated circuit (I2C) interface.

6. The reference voltage integrated circuit of claim 1, wherein:
the pin is configured to be at a first state and a second state;
when the pin is at the first state, the first reference voltage is selected; and
when the pin is at the second state, the second reference voltage is selected.

7. The reference voltage integrated circuit of claim 6, comprising:
a second pin configured to be at a third state and a fourth state; and
wherein:
the output voltage selection is configured to be selectable between the first value, the second value, and a third value corresponding to a third reference voltage;
when the pin is at the first state and the second pin is at the fourth state, the first reference voltage is selected;
when the pin is at the second state and the second pin is at the fourth state, the second reference voltage is selected;
when the pin is at the second state and the second pin is at the third state, the third reference voltage is selected; and
when the pin is at the first state and the second pin is at the third state, the reference voltage integrated circuit is placed in a shutdown state.

8. A method, comprising:
storing, in a volatile memory, an output voltage selection, the output voltage selection selectable between a first value corresponding to a first reference voltage and a second value corresponding to a second reference voltage;
selecting between the first reference voltage and the second reference voltage; and
outputting, using a reference voltage output pin, the selected reference voltage.

9. The method of claim 8, comprising storing, in a non-volatile memory, a first trim register and a second trim register, the first trim register corresponding to the first value corresponding to the first reference voltage and the second trim register corresponding to the second value corresponding to the second reference voltage.

10. The method of claim 8, comprising:
communicatively coupling a control circuit; and
receiving, from the control circuit, a command to select between the first value of the output voltage selection and the second value of the output voltage selection.

11. The method of claim 10, comprising receiving, from the control circuit, a command to place a reference voltage integrated circuit in a shutdown state.

12. The method of claim 10, wherein the control circuit is communicatively coupled using an inter-integrated circuit (I2C) interface.

13. The method of claim 8, comprising:
setting a pin to a first state or a second state;
selecting the first reference voltage when the pin is at the first state; and
selecting the second reference voltage when the pin is at the second state.

14. The method of claim 8, comprising:
setting a first pin to a first state or a second state;
setting a second pin to a third state and a fourth state, wherein the output voltage selection is configured to be selectable between the first value, the second value, and a third value corresponding to a third reference voltage;
selecting the first reference voltage when the first pin is at the first state and the second pin is at the fourth state;
selecting the second reference voltage when the first pin is at the second state and the second pin is at the fourth state;
selecting the third reference voltage when the first pin is at the second state and the second pin is at the third state; and
placing a reference voltage integrated circuit in a shutdown state when the first pin is at the first state and the second pin is at the third state.

15. A reference voltage integrated circuit, comprising:
a volatile memory for storing an output voltage selection, the output voltage selection selectable between a first value corresponding to a first reference voltage and a second value corresponding to a second reference voltage;
a non-volatile memory for storing a first trim register and a second trim register, the first trim register corresponding to the first value corresponding to the first reference voltage and the second trim register corresponding to the second value corresponding to the second reference voltage;
a pin for selecting between the first reference voltage and the second reference voltage; and
a reference voltage output pin for outputting the selected reference voltage.

16. The reference voltage integrated circuit of claim 15, wherein:
the pin is configured to be communicatively coupled to a control circuit; and
the pin is configured to receive, from the control circuit, a command to select between the first value of the output voltage selection and the second value of the output voltage selection.

17. The reference voltage integrated circuit of claim 16, wherein the pin is configured to receive, from the control circuit, a command to place the reference voltage integrated circuit in a shutdown state.

18. The reference voltage integrated circuit of claim 15, wherein the first trim register and the second trim register are configured to be set during a production trimming process.

19. The reference voltage integrated circuit of claim 15, wherein:
the pin is configured to be at a first state and a second state;
when the pin is at the first state, the first reference voltage is selected; and
when the pin is at the second state, the second reference voltage is selected.

20. The reference voltage integrated circuit of claim 19, comprising:
a second pin configured to be at a third state and a fourth state; and
wherein:
the output voltage selection is configured to be selectable between the first value, the second value, and a third value corresponding to a third reference voltage;
when the pin is at the first state and the second pin is at the fourth state, the first reference voltage is selected;
when the pin is at the second state and the second pin is at the fourth state, the second reference voltage is selected;
when the pin is at the second state and the second pin is at the third state, the third reference voltage is selected; and
when the pin is at the first state and the second pin is at the third state, the reference voltage integrated circuit is placed in a shutdown state.
